(19) United States
(12) Patent Application Publication
(10) Pub. No.: US 2004/0061219 A1
(43) Pub. Date: Apr. 1, 2004

(54) Semiconductor device

(75) Inventor: Hiromitsu Utsumi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/454,498

(22) Filed: Jun. 5, 2003

(30) Foreign Application Priority Data
Sep. 30, 2002 (JP) 2002-286257

(51) Int. Cl. H01L 23/34

(52) U.S. Cl. 257/718

(57) ABSTRACT

An internally matching type transistor includes a semiconductor element and an internally matching circuit, and includes a resonant circuit for short-circuiting differential frequencies of two signals of different frequencies is employed as the internally matching circuit. Thereby, intermodulation distortion characteristics in the internally matching type transistor 1 can be improved. Therefore, complicated operations, such as adjustment by externally connecting a resonant circuit to a semiconductor device, can be eliminated, and the internally matching type transistor 1 of improved intermodulation distortion characteristics can be provided as a stand-alone part.

### BACKGROUND OF THE INVENTION

1. Field of the Invention

The present invention relates to a semiconductor device, and more particularly to a semiconductor device comprising an internally matching circuit.

2. Background Art

FIG. 11 is a schematic diagram showing a conventional internally matching transistor 101 having a circuit for processing higher harmonic waves, and the surroundings thereof. As shown in FIG. 11, the internally matching transistor 101 comprises circuits, such as a lumped-constant circuit 102 and an FET 103, as internal circuits.

In such an internally matching transistor 101, intermodulation distortion (IMD) must be improved to elevate a purity of signals. Intermodulation distortion means the appearance of mixed signals in the like zones by mutual modulation due to higher non-linear characteristics when a plurality of signals are inputted in an internally matching transistor 101. For example, intermodulation distortion characteristics by third non-linear characteristics are called third intermodulation distortion characteristics (IM3); and intermodulation distortion by fifth non-linear characteristics is called fifth intermodulation distortion characteristics (IM5).

Therefore, as shown in FIG. 11, an intermodulation distortion characteristics improving circuit 104 is externally connected to an internally matching transistor 101. The intermodulation distortion characteristics improving circuit 104 is composed of a distributed parameter line 105 having a line length of ¼λ of the fundamental wave fₒ and a capacitor 106 having a short-circuiting impedance (0.1 Ω or below), and short-circuits the differential frequency Δf of the two RF frequencies.

However, intermodulation distortion characteristics cannot be improved sufficiently, and desired functions cannot be obtained only by externally connecting the intermodulation distortion characteristics improving circuit 104 to the internally matching transistor 101. For this reason, it is required to make the desired functions exert by mutually adjusting the internally matching transistor 101 and the intermodulation distortion characteristics improving circuit 104. Therefore, users of the device had to carry out complicated operations of connecting an intermodulation distortion characteristics improving circuit 104 to the internally matching transistor 101, and further adjusting them.

Furthermore, a problem of increase in the size of the entire device has arisen by externally connecting the intermodulation distortion characteristics improving circuit 104 to the internally matching transistor 101. In addition, since the internally matching transistor 101 and the intermodulation distortion characteristics improving circuit 104 must be manufactured and quality-controlled separately, the manufacturing and control processes become complicated, resulting in increase in manufacturing costs.

### SUMMARY OF THE INVENTION

The present invention is achieved for solving the above-described problems, and an object of the present invention is to provide an internally matching transistor having improved intermodulation distortion characteristics.

According to one aspect of the present invention, a semiconductor device comprises a semiconductor element and an internally matching circuit. A resonant circuit for short-circuiting differential frequencies of two signals of different frequencies is employed as the internal circuit.

Since a resonant circuit for short-circuiting the differential frequency is provided on an internal circuit, intermodulation distortion characteristics can be improved within the semiconductor device. Therefore, no complicated operations, such as adjustment by externally connecting a resonant circuit to the semiconductor device, are required, and a semiconductor device having improved intermodulation distortion characteristics can be provided as a stand-alone part.

Other and further objects, features and advantages of the invention will appear more fully from the following description.

### BRIEF DESCRIPTION OF THE DRAWINGS

FIG. 1 is a schematic diagram showing a semiconductor device according to a first embodiment of the present invention.

FIG. 2 is a schematic diagram showing another aspect of the internally matching transistor 1.

FIG. 3 is a schematic diagram showing an internally matching transistor according to a second embodiment of the present invention.

FIG. 4 is a schematic diagram showing a third embodiment of the present invention.

FIG. 5 is a schematic diagram showing a fourth embodiment of the present invention.

FIGS. 6A and 6B are schematic diagrams showing a fifth embodiment of the present invention.

FIG. 7 is a schematic diagram showing a sixth embodiment of the present invention.

FIGS. 8A and 8B are schematic diagrams showing a seventh embodiment of the present invention.

FIG. 9 is a schematic diagram showing an eighth embodiment of the present invention.

FIG. 10 is a schematic diagram showing a ninth embodiment of the present invention.

FIG. 11 is a schematic diagram showing a conventional internally matching transistor having a circuit for processing higher harmonic waves, and the surroundings thereof.

### DETAILED DESCRIPTION OF THE PREFERRED EMBODIMENTS

Some embodiments of the present invention will be described in detail below referring to the drawings. The present invention is in no way limited by the embodiments described below. In each embodiment described below, common constituents will be denoted by the same reference numerals and characters, and part of the description thereof will be omitted.

First Embodiment

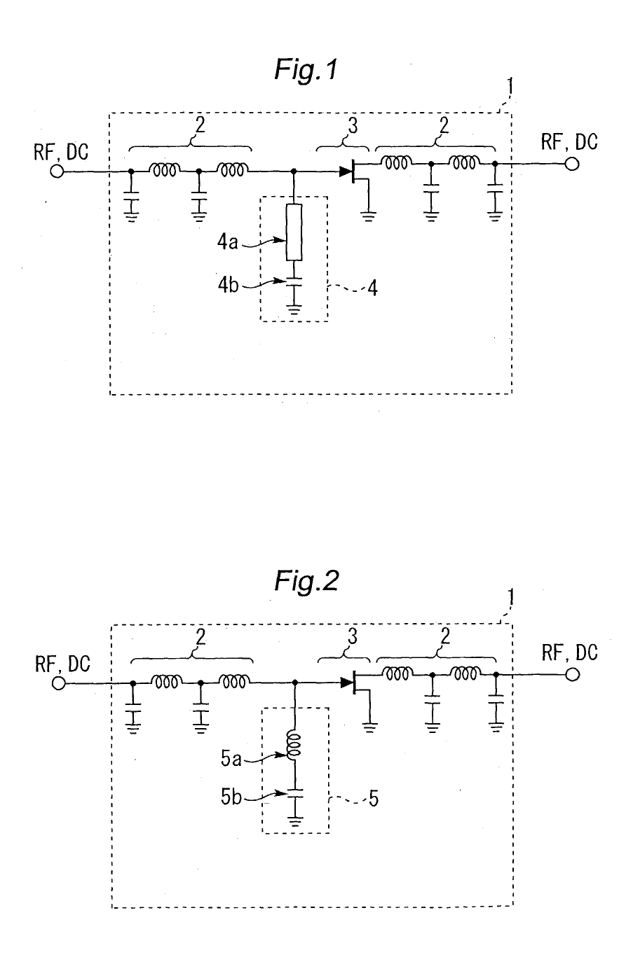

FIG. 1 is a schematic diagram showing a semiconductor device according to a first embodiment of the present invention. The semiconductor device shown in FIG. 1 is an internally matching transistor 1 having a circuit for processing higher harmonic waves, wherein internal circuits, such as a lumped-constant circuit 2 and an FET 3 are contained.

As shown in FIG. 1, an intermodulation distortion characteristics improving circuit 4 is connected between the lumped-constant circuit 2 and the FET 3 to improve an intermodulation distortion characteristics. The intermodulation distortion characteristics improving circuit 4 is a resonant circuit for the differential frequency Δf of two RF frequencies, which is composed of a distributed parameter line (micro-strip line) 4a of a line length equivalent to ¼λ of the wavelength (λ) of the fundamental wave fₒ and a capacitor 4b having a short-circuiting impedance.

FIG. 2 is a schematic diagram showing another aspect of the internally matching transistor 1. In FIG. 2, the constitution other than an intermodulation distortion characteristics improving circuit 5 is the same as the embodiment shown in FIG. 1. The intermodulation distortion characteristics improving circuit 5 is also a resonant circuit for the differential frequency Δf, which is composed of an inductor 5a having infinite impedance relative to a fundamental wave fₒ, and a capacitor 5b.

Thus, by short-circuiting the differential frequency (Δf) of two frequencies in the case of two-wave input, mainly third intermodulation distortion characteristics (IM3) can be improved, and intermodulation distortion characteristics can be improved. The improvement of third intermodulation distortion characteristics (IM3) can also result in the improvement of fifth intermodulation distortion characteristics (IM5). The inductor and the capacitor used in the resonant circuit can be derived from the following equation.

F(Hz)=1/(2π√(LC))

Here, it is required that L used in the resonant circuit has infinite impedance to fundamental wave fₒ.

In FIGS. 1 and 2, although intermodulation distortion characteristics improving circuits 4 and 5 are connected between the lumped-constant circuit 2 and the FET 3, the place of connection is not limited thereto, but the desired effect can be obtained when these are connected to other places, such as the vicinity of the external terminal.

According to the first embodiment, since intermodulation distortion characteristics improving circuits 4 and 5 are provided inside the internally matching transistor 1, the internally matching transistor 1 having improved intermodulation distortion characteristics can be constituted as a discrete part. Therefore, there is no need for connecting and the adjusting an internally matching transistor and intermodulation distortion characteristics improving circuit, and users are able to purchase the internally matching transistor 1 having already improved intermodulation distortion characteristics. Furthermore, there is no need of complicated operations such as the connection of an intermodulation distortion characteristics improving circuit to the internally matching transistor.

In addition, the downsizing of the entire device can be achieved by integrating the internally matching transistor 1 and intermodulation distortion characteristics improving circuits 4 and 5. Furthermore, since the internally matching transistor and intermodulation distortion characteristics improving circuits can be manufactured and quality-controlled collectively, the manufacturing process can be simplified and the manufacturing costs can be reduced.

Second Embodiment

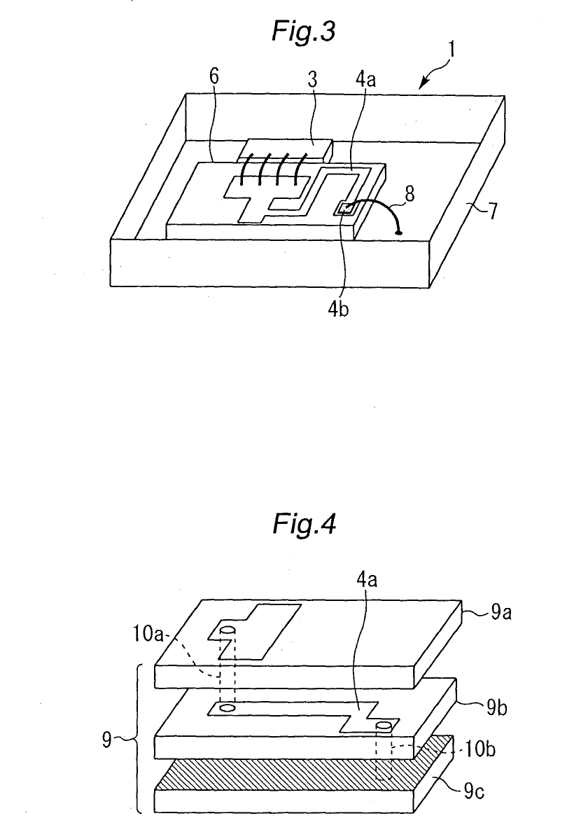

FIG. 3 is a schematic diagram showing an internally matching transistor 1 according to a second embodiment of the present invention. Each of the following embodiments is a circuit constitution shown in FIGS. 1 and 2 specifically embodied in the package of an internally matching transistor 1.

In the internally matching transistor 1 shown in FIG. 3, an internal circuit board (MIC board) 6 carrying an internally matching circuit such as a lumped-constant circuit 2 is electrically connected to an FET 3 with wires. On the internal circuit board 6 are provided a distributed parameter line 4a of a line length equivalent to ¼λ of the wavelength (λ) of the fundamental wave fₒ and a capacitor 4b. By connecting the capacitor 4b to a package 7 (GND) of the internally matching transistor 1 with wires 8, the Δf can be short-circuited with the capacitor 4b.

By thus inserting a distributed parameter line 4a in the internal circuit board 6, the circuit constitution shown in FIG. 1 can be realized by disposing the capacitor 4b on the internal circuit board 6.

According to the second embodiment, since a distributed parameter line 4a and a capacitor 4b are provided on an internal circuit board 6, the internal circuit, the distributed parameter line 4a, and the capacitor 4b can be provided on a board. Therefore, the space on the internal circuit board 6 can be utilized effectively to integrate the internally matching circuit and the resonant circuit, and to reduce the size of the package 7.

Third Embodiment

FIG. 4 is a schematic diagram showing a third embodiment of the present invention, and shows a constitution of an internal circuit board 9 used in an internally matching transistor 1. The internally matching transistor 1 of the third embodiment uses a multi-layer internal circuit board (multi-layer MIC board) 9, and has a resonant circuit on the internal circuit board 9.

The internal circuit board 9 is a laminated board composed of a plurality of circuit boards 9a to 9c. Here in FIG. 4, each of the circuit boards 9a to 9c is separately shown for the ease of description. The circuit board 9a has an internally matching circuit such as a lumped-constant circuit 2. As also shown in FIG. 4, the circuit board 9b has a distributed parameter line 4a; and the circuit board 9c has a capacitor layer that acts as a capacitor 4b. The circuit board 9a is electrically connected to the circuit board 9b with a through-hole 10a; and the circuit board 9b is electrically connected to the circuit board 9c with a through-hole 10b.

By thus using the multi-layer internal circuit board 9, the distributed parameter line 4a and the capacitor 4b can be provided on the internal circuit board 9, and a circuit constitution shown in FIG. 1 can be realized.

According to the third embodiment, by the use of the multi-layer internal circuit board 9, the internally matching circuit, the distributed parameter line 4a, and the capacitor 4b can be arranged in the internal circuit board 9 collectively. Therefore, the space on the internal circuit board 9 can be utilized effectively to provide a resonant circuit in the internally matching transistor 1, and the downsizing of the package 7 can be achieved.

Fourth Embodiment

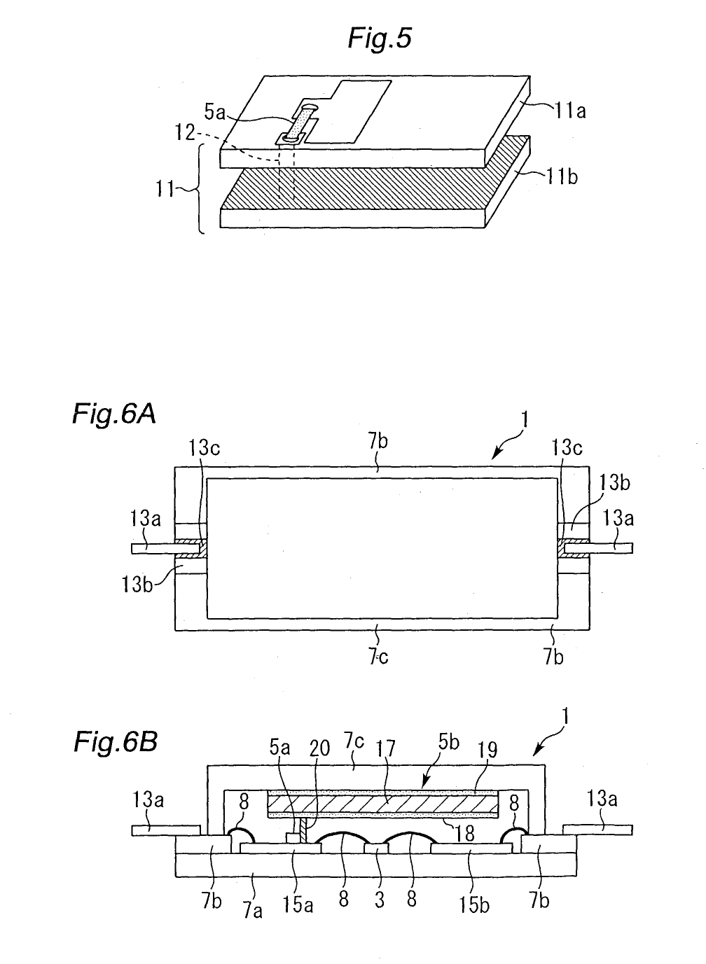

FIG. 5 is a schematic diagram showing a fourth embodiment of the present invention, and shows a constitution of an internal circuit board 11 used in an internally matching transistor 1. The internally matching transistor 1 of the fourth embodiment uses a multi-layer internal circuit board (multi-layer MIC board) 11 as in the third embodiment, and uses an inductor 5a having infinite impedance as the resonant circuit.

The internal circuit board 11 is a laminated board composed of circuit boards 11a and 11b. In also FIG. 5, each of the circuit boards 11a and 11b is separately shown as in FIG. 4. The circuit board 11a has an internally matching circuit such as a lumped-constant circuit 2. An inductor 5a is provided on the circuit board 11a, and the internally matching circuit is electrically connected to the inductor 5a.

As shown in FIG. 5, the circuit board 11b has a capacitor layer that acts as a capacitor 5b. The circuit board 11a is electrically connected to the circuit board 11b with a through-hole 12.

By thus using the multi-layer internal circuit board 11, the inductor 5a and the capacitor 5b can be provided on the internal circuit board 11, and the circuit constitution shown in FIG. 2 can be realized.

According to the fourth embodiment, by the use of the multi-layer internal circuit board 11, the internally matching circuit, the inductor 5a and the capacitor 5b can be arranged in the internal circuit board 11 collectively, and the downsizing of the package 7 can be achieved.

Fifth Embodiment

FIG. 6 is a schematic diagram showing a fifth embodiment of the present invention. Here, FIG. 6A is a plan of an internally matching transistor 1; and FIG. 6B is a sectional side view thereof. In the fifth embodiment a capacitor 5b is provided on the cap (cover) 7c of the package 7.

As shown in FIGS. 6A and 6B, the package 7 of the internally matching transistor 1 is composed of a base 7a, a frame 7b, and a cap 7c. In this constitution, the frame 7b is placed on the base 7a, and the cap 7c is put on the frame 7b. A predetermined space is formed between the base 7a and the cap 7c.

In the package 7, an FET 3 and internal circuit boards 15a and 15b are disposed, and the FET 3 is electrically connected to the internal circuit boards 15a and 15b with wires 8, respectively.

An inductor 5a is disposed on the internal circuit board 15a. A capacitor 5b is provided to the cap 7c of the package 7. The capacitor 5b is composed of an inductor 17, an electrode 18, and a ground electrode 19. The internal circuit board 15a is electrically connected to the electrode 18 with a contact line 20. The ground electrode 19 is connected to the ground wiring on the base 7a with a predetermined pattern and a through-hole.

As shown in FIG. 6A shows, a ceramic board 13b is inserted into a predetermined location of the frame 7b, and a conductive pattern 13c is formed on the ceramic board 13b. A lead terminal 13a is fixed on the conductive pattern 13c, and the conductive pattern 13c is electrically connected to the lead terminal 13a. The internal circuit boards 15a and 15b are electrically connected to the ceramic board 13b with wires 8.

By thus disposing the inductor 5a on the internal circuit board 15a, and disposing the capacitor 5b on the cap 7c, the circuit constitution shown in FIG. 2 can be realized.

According to the fifth embodiment, since the capacitor 5b is provided on the cap 7c of the package 7, the space in the upward direction in the package 7 can be utilized effectively to dispose the capacitor 5b, and the downsizing of the package 7 can be achieved.

Sixth Embodiment

FIG. 7 is a schematic diagram showing a sixth embodiment of the present invention, and is a plan showing the vicinity of the lead terminal 13a.

Similarly as the fifth embodiment, a ceramic board 13b is inserted into a predetermined location of the frame 7b, and the lead terminal 13a is fixed on the conductive pattern 13c on the ceramic board 13b. In the sixth embodiment, a ground terminal 14 consisting of the same pattern as the conductive pattern 13c is provided on the ceramic board 13b. The ground terminal 14 is connected to the ground wiring on the base 7a. Between the conductive pattern 13c and the ground terminal 14 are disposed an inductor 5a and a capacitor 5b. The lead terminal 13a and the inductor 5a, the inductor 5a and the capacitor 5b, the capacitor 5b and the ground terminal 14, are electrically connected, respectively.

By thus providing the ground terminal 14 on the ceramic board 13b, and disposing the inductor 5a and the capacitor 5b between the lead terminal 13a and the ground terminal 14, the circuit constitution shown in FIG. 2 can be realized. Although the inductor 5a, the capacitor 5b, and the ground terminal 14, are symmetrically disposed on the both sides of the lead terminal 13a, these may be disposed on one side thereof.

According to the sixth embodiment, since the inductor 5a and the capacitor 5b are mounted on the ceramic board 13b on which the lead terminal 13a is fixed, the inductor 5a and the capacitor 5b can be disposed in the internally matching transistor 1 without using the space in the package 7. Thereby, the downsizing of the package 7 can be achieved.

Seventh Embodiment

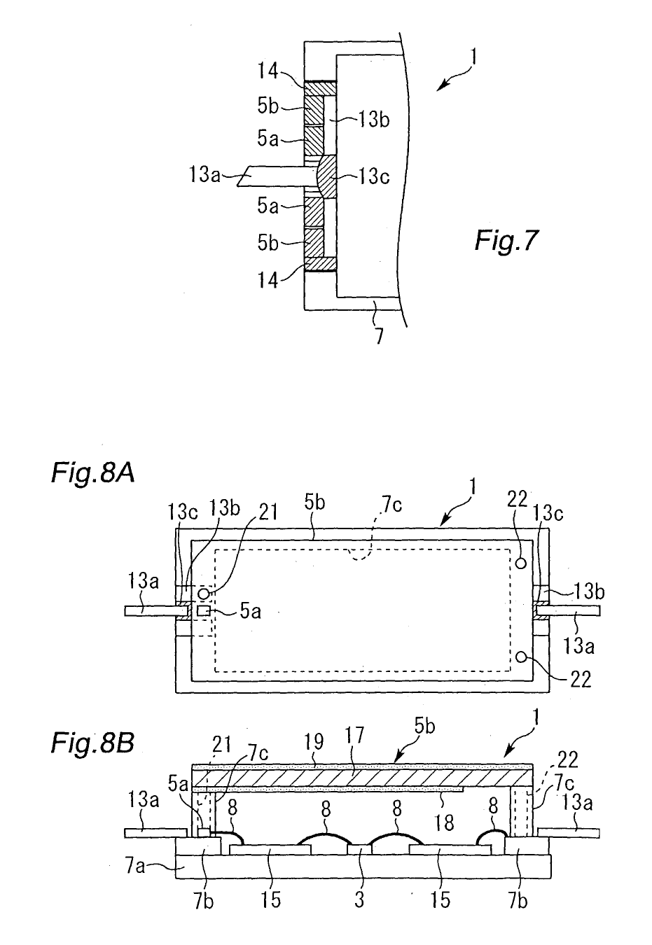

FIG. 8 is a schematic diagram showing a seventh embodiment of the present invention. Here, FIG. 8A is a plan of an internally matching transistor 1; and FIG. 8B is a sectional side view thereof. In the seventh embodiment, and the capacitor 5b is provided on the cap 7c of the package 7, and the inductor 5a is provided on a feed-through portion of the lead terminal 13a.

Similarly as the fifth and sixth embodiments, the lead terminal 13a is fixed on the conductive pattern 13c, and the conductive pattern 13c constitutes the feed-through portion into the package 7. In the seventh embodiment, the inductor 5a is fixed on the conductive pattern 13c of the feed-through portion, and the lead terminal 13a is electrically connected to the inductor 5a. The electrode 18of the capacitor 5b is electrically connected to the inductor 5a through a through-hole 21 formed in the cap 7c. Also, the ground electrode 19 of the capacitor 5b is electrically connected to the ground wiring on the base 7a through a through-hole 22 formed in the cap 7c.

As shown in FIG. 8B, an FET 3 and internal circuit boards 15 are disposed in the package 7. Wires 8 are connected to conductive patterns 13c, and the lead terminals 13a are electrically connected to the internal circuit boards 15 with the wires 8. The FET 3 is also electrically connected to the internal circuit boards 15 with the wires 8.

By thus disposing the inductor 5a on the feed-through portion of the lead terminal 13a, and connecting the inductor 5a to the capacitor 5b through the through-hole 21, the circuit constitution shown in FIG. 2 can be realized.

According to the seventh embodiment, since the capacitor 5b is provided on the cap portion 7c of the package 7, the capacitor 5b can be disposed effectively utilizing the space in the upward direction of the package 7. Also since the inductor 5a is disposed in the vicinity of the feed-through portion, the inductor 5a can be disposed in the state where the space occupation in the package 7 is minimized. Thereby, the downsizing of the package 7 can be achieved.

Eighth Embodiment

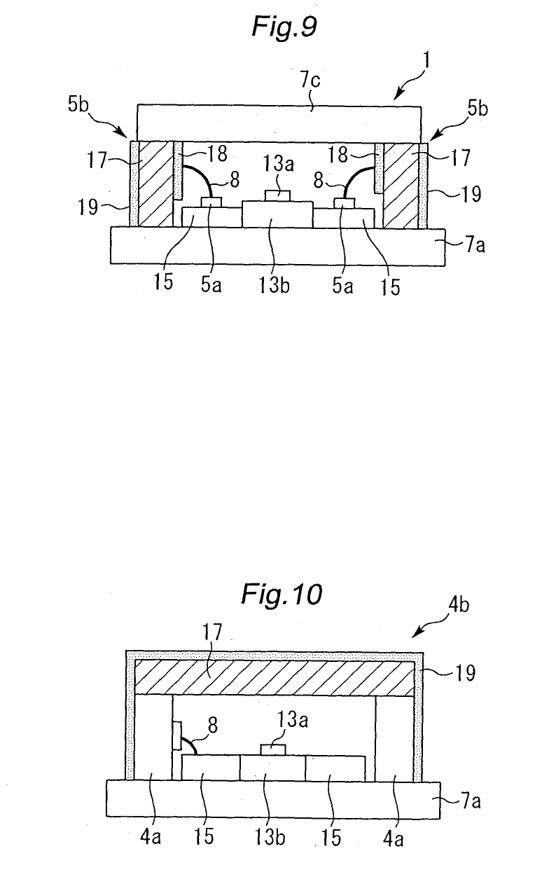

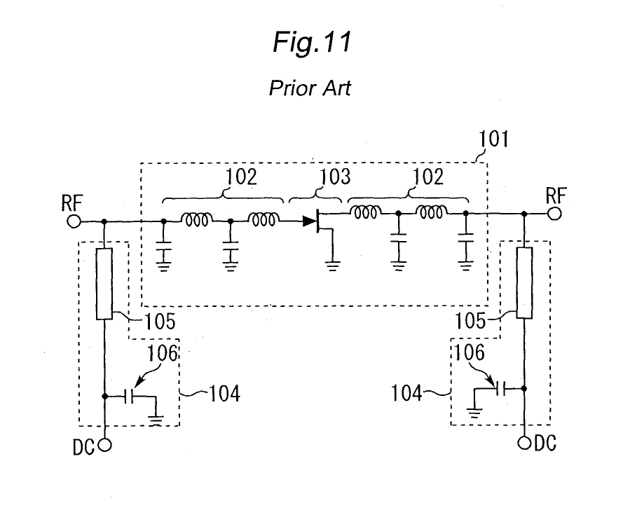

FIG. 9 is a schematic diagram showing an eighth embodiment of the present invention, and is a schematic sectional view showing a cross-section of the package 7 of an internally matching transistor 1. In the eighth embodiment, capacitors 5b are provided on the sidewalls of the package 7. In FIGS. 6B and 8B, cross-sections along the lengthwise direction of two lead terminals 13a are shown; however, in FIG. 9, a cross-section in the direction perpendicular to the lengthwise direction of the lead terminals 13a is shown.

As shown in FIG. 9, capacitors 5b are formed on the sidewalls of the package 7. As in the fifth embodiment, each capacitor 5b is composed of an inductor 17, an electrode 18, and a ground electrode 19; and is constituted so that the electrode 18 is positioned inside the package 7, and the ground electrode 19 is positioned outside the package 7.

As in the fifth, sixth, and seventh embodiments, the ceramic board 13b whereon a lead terminal 13a is fixed is provided on the base 7a of the package 7. Internal circuit boards 15 having inductors 5b are disposed in the package 7. The inductors 5a are electrically connected to the electrode 18 with wires 8. The ground electrodes 19 are electrically connected to the ground wirings on the base 7a, and the lead terminal 13a is electrically connected to internal circuit boards 15.

By thus providing capacitors 5b on the sidewalls of the package 7, and connecting them to inductors 5a on the internal circuit boards 15, the circuit constitution shown in FIG. 2 can be realized.

According to the eighth embodiment, since the sidewalls of the package 7 are integrated with capacitors 5b, the capacitor 5b can be disposed in the state where the space occupation in the package 7 is minimized. Thereby, the downsizing of the package 7 can be achieved.

Ninth Embodiment

FIG. 10 is a schematic diagram showing a ninth embodiment of the present invention, and is a schematic sectional view showing a cross-section of the package 7 of an internally matching transistor 1. FIG. 10 also shows the cross section in the direction perpendicular to the lengthwise direction of the lead terminal 13a as in FIG. 9. In the ninth embodiment, a capacitor 4b is provided on the cap 7c of the package 7, and distributed parameter line 4a is provided on the sidewall of the package 7.

As shown in FIG. 10, the capacitor 4b is formed on the cap 7c of the package 7. The capacitor 4b is composed of an inductor 17 and a ground electrode 19, and is disposed so that the ground electrode 19 is outside the package 7.

As in the eighth embodiment, a ceramic board 13b whereon a lead terminal 13a is fixed is provided on the base 7a of the package 7, and internal circuit boards 15 are disposed on the both sides of the ceramic board 13b. The lead terminal 13a is electrically connected to the internal circuit boards 15.

Distributed parameter lines 4a are disposed on the sidewalls of the package 7. One of the distributed parameter lines 4a is electrically connected to one of internal circuit boards 15 with a wire 8. By allowing the inductor 17 of the capacitor 4b to contact distributed parameter lines 4a directly, the distributed parameter lines 4a are electrically connected to the capacitor 4b. The ground electrode 19 is also electrically connected to the ground wirings on the base 7a.

By thus providing distributed parameter lines 4a on the sidewalls of the package 7 to connect to the capacitor 4b, and by connecting the distributed parameter lines 4a to the internal circuit boards 15 with wires 8, the circuit constitution shown in FIG. 1 can be realized.

According to the ninth embodiment, since the sidewall of the package 7 is integrated with distributed parameter lines 4a, the distributed parameter lines 4a can be disposed in the state where the space occupation in the package 7 is minimized. Thereby, the downsizing of the package 7 can be achieved.

Since the present invention is constituted as described above, it has the following effects.

Since a resonant circuit for short-circuiting the differential frequency is provided on an internal circuit, intermodulation distortion characteristics can be improved within the semiconductor device. Therefore, no complicated operations, such as adjustment by externally connecting a resonant circuit to the semiconductor device, are required, and a semi conductor device having improved intermodulation distortion characteristics can be provided as a stand-alone part.

By constituting a resonant circuit using a distributed parameter line having a line length equivalent to the ¼ wavelength of one of two signals, and a capacitor, the intermodulation distortion characteristics can surely be improved.

By constituting a resonant circuit using an inductor having infinite impedance to the fundamental wave, and a capacitor, the intermodulation distortion characteristics can surely be improved.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-286257, filed on Sep. 3, 2002 including specification, claims, drawings and summary, on which the Convention priority of the present application is based, are incorporated herein by reference in its entirety.

1. A semiconductor device, comprising:
a semiconductor element; and
an internally matching circuit,
wherein a resonant circuit for short-circuiting differential frequencies of two signals of different frequencies is employed as the internal circuit.

2. The semiconductor device according to claim 1, wherein said resonant circuit comprises a distributed parameter line of a line length equivalent to ¼ wavelength of one of said signals, and a capacitor.

3. The semiconductor device according to claim 1, wherein said resonant circuit comprises an inductor having an infinite impedance relative to a fundamental wave, and a capacitor.
